(19) United States
(12) Patent Application Publication
(10) Pub. No.: US 2006/0180174 A1
(43) Pub. Date: Aug. 17, 2006

(54) METHOD AND SYSTEM FOR TREATING A SUBSTRATE WITH A HIGH PRESSURE FLUID USING A PEROXIDE-BASED PROCESS CHEMISTRY IN CONJUNCTION WITH AN INITIATOR

(75) Inventor: Robert Kevwitch, Chandler, AZ (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 10/906,350

(22) Filed: Feb. 15, 2005

(51) Int. Cl. C23C 16/00; B08B 6/00; B08B 3/00

(52) U.S. Cl. 134/1.3; 427/248.1; 134/56 R

(57) ABSTRACT

A method and system is described for treating a substrate with a high pressure fluid, such as carbon dioxide in a supercritical state. A process chemistry containing a process peroxide is introduced to the high pressure fluid for treating the substrate surface. The peroxide-based chemistry is used in conjunction with an initiator, wherein the initiator facilitates the formation of a radical of the process peroxide.

### CROSS-REFERENCE TO RELATED APPLICATIONS

This application is related to co-pending U.S. patent application Ser. No. 11/______, entitled “Method for Treating a Substrate With a High Pressure Fluid Using a Peroxide-Based Process Chemistry”, Attorney Docket No. SSIT-128, filed on even date herewith; co-pending U.S. patent application Ser. No. 10/987,067, entitled “Method and System for Treating a Substrate Using a Supercritical Fluid”, Attorney Docket No. SSIT-117, filed on Nov. 12, 2004; co-pending U.S. patent application Ser. No. 10/987,066, entitled “Method and System for Cooling a Pump”, Attorney Docket No. SSIT-120, filed on Nov. 12, 2004; co-pending U.S. patent application Ser. No. 10/987,594, entitled “A Method for Removing a Residue From a Substrate Using Supercritical Carbon Dioxide Processing”, Attorney Docket No. SSIT-073, filed on Nov. 12, 2004; and co-pending U.S. patent application Ser. No. 10/987,676, entitled “A System for Removing a Residue From a Substrate Using Supercritical Carbon Dioxide Processing”, Attorney Docket No. SSIT-125, filed on Nov. 12, 2004. The entire contents of these applications are herein incorporated by reference in their entirety.

### FIELD OF THE INVENTION

The present invention relates to a method and system for treating a substrate in a high pressure processing system and, more particularly, to a method and system for treating a substrate using a supercritical fluid, a process peroxide, and an initiator in a high pressure processing system, wherein the initiator facilitates the formation of a radical of the process peroxide.

### DESCRIPTION OF RELATED ART

During the fabrication of semiconductor devices for integrated circuits (ICs), a sequence of material processing steps, including both pattern etching and deposition processes, are performed, whereby material is removed from or added to a substrate surface, respectively. During, for instance, pattern etching, a pattern formed in a mask layer of radiation-sensitive material, such as photoresist, using for example photolithography, is transferred to an underlying thin material film using a combination of physical and chemical processes to facilitate the selective removal of the underlying material film relative to the mask layer.

Thereafter, the remaining radiation-sensitive material, or photoresist, and post-etch residue, such as hardened photoresist and other etch residues, are removed using one or more cleaning processes. Conventionally, these residues are removed by performing plasma ashing in an oxygen plasma, followed by wet cleaning through immersion of the substrate in a liquid bath of stripper chemicals.

Until recently, dry plasma ashing and wet cleaning were found to be sufficient for removing residue and contaminants accumulated during semiconductor processing. However, recent advancements for ICs include a reduction in the critical dimension for etched features below a feature dimension acceptable for wet cleaning, such as a feature dimension below approximately 45 to 65 nanometers (nm). Moreover, the advent of new materials, such as low dielectric constant (low-k) materials, limits the use of plasma ashing due to their susceptibility to damage during plasma exposure.

Therefore, at present, interest has developed for the replacement of dry plasma ashing and wet cleaning. One interest includes the development of dry cleaning systems utilizing a supercritical fluid as a carrier for a solvent, or other residue removing composition. At present, the inventors have recognized that conventional processes are deficient in, for example, cleaning residue from a substrate, particularly those substrates following complex etching processes, or having high aspect ratio features.

### SUMMARY OF THE INVENTION

The present invention provides a method and system for treating a substrate with a high pressure fluid and a process chemistry in a high pressure processing system. In one embodiment of the invention, there is provided a method and system for treating a substrate with a high pressure fluid, a process peroxide, and an initiator in a high pressure processing system. The initiator facilitates the formation of a radical of the process peroxide.

According to another embodiment, the method includes placing the substrate in a high pressure processing chamber onto a platen configured to support the substrate; forming a supercritical fluid from a fluid by adjusting a pressure of the fluid above the critical pressure of the fluid, and adjusting a temperature of the fluid above the critical temperature of the fluid; introducing the supercritical fluid to the high pressure processing chamber; introducing a process chemistry comprising a process peroxide to the supercritical fluid; introducing an initiator to the supercritical fluid, wherein the initiator facilitates the formation of a radical of the process peroxide; and exposing the substrate to the supercritical fluid, process chemistry and initiator.

According to yet another embodiment, the high pressure processing system includes a processing chamber configured to treat the substrate; a platen coupled to the processing chamber, and configured to support the substrate; a high pressure fluid supply system configured to introduce a supercritical fluid to the processing chamber; a fluid flow system coupled to the processing chamber, and configured to flow the supercritical fluid over the substrate in the processing chamber; a process chemistry supply system having a peroxide source configured to introduce a process peroxide; an initiator source configured to introduce an initiator to facilitate the formation of a radical of the process peroxide; and a temperature control system coupled to one or more of the processing chamber, the platen, the high pressure fluid supply system, the fluid flow system, and the process chemistry supply system, and configured to elevate the supercritical fluid to a temperature approximately equal to 40° C., or greater.

### BRIEF DESCRIPTION OF THE DRAWINGS

In the accompanying drawings:

FIG. 1 presents a simplified schematic representation of a processing system;

FIG. 2A depicts a system configured to cool a pump;

FIG. 2B depicts another system configured to cool a pump;

FIG. 3 presents another simplified schematic representation of a processing system;

FIG. 4 presents another simplified schematic representation of a processing system;

FIG. 5 presents another simplified schematic representation of a processing system;

FIGS. 6A and 6B depict a fluid injection manifold for introducing fluid to a processing system; and

FIG. 7 illustrates a method of treating a substrate in a processing system according to an embodiment of the invention.

### DETAILED DESCRIPTION OF EXEMPLARY EMBODIMENTS

In the following description, to facilitate a thorough understanding of the invention and for purposes of explanation and not limitation, specific details are set forth, such as a particular geometry of the processing system and various descriptions of the system components. However, it should be understood that the invention may be practiced with other embodiments that depart from these specific details.

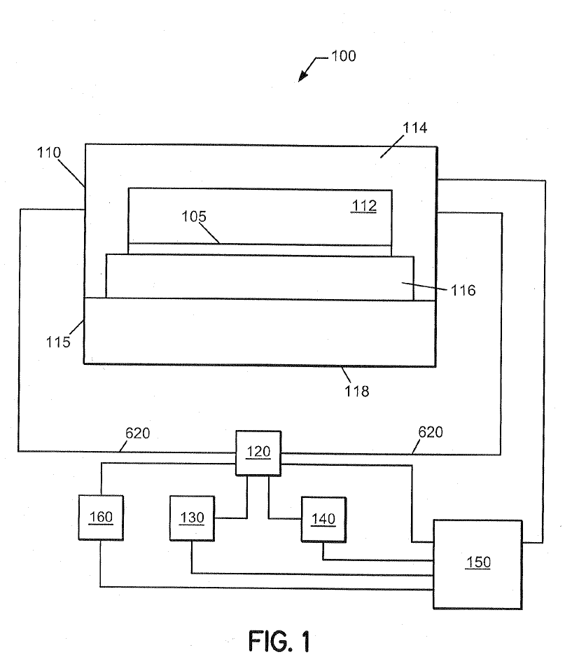

Referring now to the drawings, wherein like reference numerals designate identical or corresponding parts throughout the several views, FIG. 1 illustrates a processing system 100 according to an embodiment of the invention. In the illustrated embodiment, processing system 100 is configured to treat a substrate 105 with a high pressure fluid, such as a fluid in a supercritical state, a process peroxide, and an initiator. The processing system 100 comprises processing elements that include a processing chamber 110, a fluid flow system 120, a process chemistry supply system 130, a high pressure fluid supply system 140, an initiator source 160, and a controller 150, all of which are configured to process substrate 105. The controller 150 can be coupled to the processing chamber 110, the fluid flow system 120, the process chemistry supply system 130, the high pressure fluid supply system 140, and the initiator source 160.

Alternately, or in addition, controller 150 can be coupled to a one or more additional controllers/computers (not shown), and controller 150 can obtain setup and/or configuration information from an additional controller/computer.

In FIG. 1, singular processing elements (110, 120, 130, 140, 160, and 150) are shown, but this is not required for the invention. The processing system 100 can comprise any number of processing elements having any number of controllers associated with them in addition to independent processing elements.

The controller 150 can be used to configure any number of processing elements (110, 120, 130, 140, and 160), and the controller 150 can collect, provide, process, store, and display data from processing elements. The controller 150 can comprise a number of applications for controlling one or more of the processing elements. For example, controller 150 can include a graphic user interface (GUI) component (not shown) that can provide easy to use interfaces that enable a user to monitor and/or control one or more processing elements.

Referring still to FIG. 1, the fluid flow system 120 is configured to flow fluid and chemistry from the supplies 130 and 140 through the processing chamber 110. The fluid flow system 120 is illustrated as a recirculation system through which the fluid and chemistry recirculate from and back to the processing chamber 110 via primary flow line 620. This recirculation is most likely to be the preferred configuration for many applications, but this is not necessary to the invention. Fluids, particularly inexpensive fluids, can be passed through the processing chamber 110 once and then discarded, which might be more efficient than reconditioning them for re-entry into the processing chamber. Accordingly, while the fluid flow system or recirculation system 120 is described as a recirculating system in the exemplary embodiments, a non-recirculating system may, in some cases, be substituted. This fluid flow system 120 can include one or more valves (not shown) for regulating the flow of a processing solution through the fluid flow system 120 and through the processing chamber 110. The fluid flow system 120 can comprise any number of back-flow valves, filters, pumps, and/or heaters (not shown) for maintaining a specified temperature, pressure or both for the processing solution and for flowing the process solution through the fluid flow system 120 and through the processing chamber 110. Furthermore, any one of the many components provided within the fluid flow system 120 may be heated to a temperature consistent with the specified process temperature.

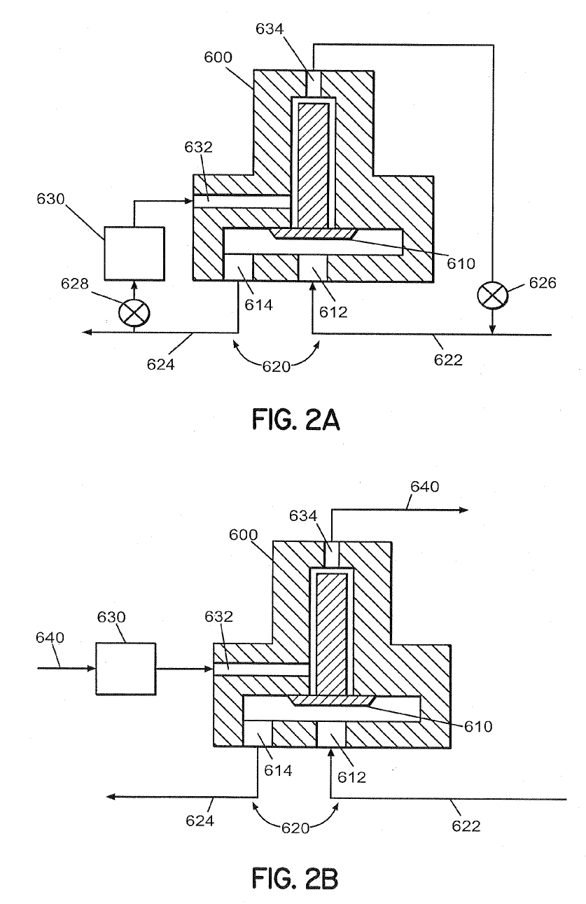

Some components, such as a fluid flow or recirculation pump, may require cooling in order to permit proper functioning. For example, some commercially available pumps, having specifications required for processing performance at high pressure and cleanliness during supercritical processing, comprise components that are limited in temperature. Therefore, as the temperature of the fluid and structure are elevated, cooling of the pump is required to maintain its functionality. Fluid flow system 120 for circulating the supercritical fluid through processing chamber 110 can comprise a primary flow line 620 coupled to high pressure processing chamber 110, and configured to supply the supercritical fluid at a fluid temperature above the critical temperature of the fluid, for example equal to or greater than 40° C., to the high pressure processing chamber 110, and a high temperature pump 600, shown and described below with reference to FIGS. 2A and 2B, coupled to the primary flow line 620. The high temperature pump 600 can be configured to move the supercritical fluid through the primary flow line 620 to the processing chamber 110, wherein the high temperature pump comprises a coolant inlet configured to receive a coolant and a coolant outlet configured to discharge the coolant. A heat exchanger coupled to the coolant inlet can be configured to lower a coolant temperature of the coolant to a temperature less than or equal to the fluid temperature of the supercritical fluid.

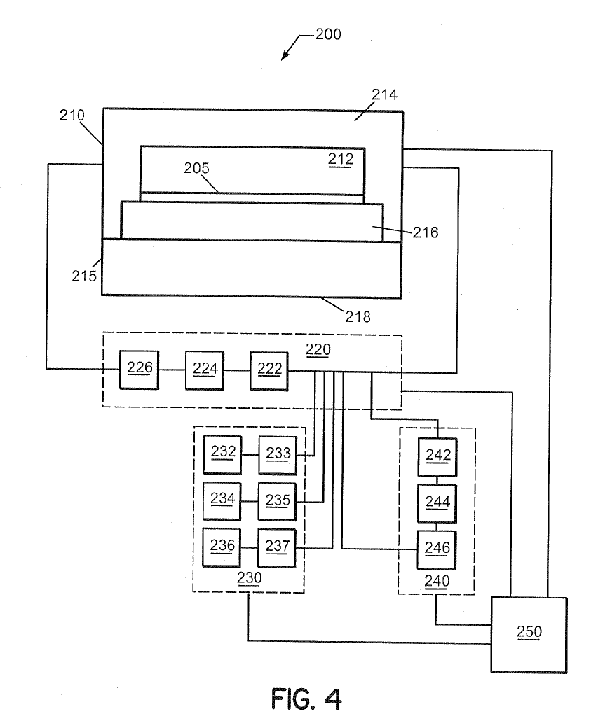

As illustrated in FIG. 2A, one embodiment is provided for cooling a high temperature pump 600 associated with fluid flow system 120 (or 220 described below with reference to FIG. 4) by diverting high pressure fluid from a primary flow line 620 to the high pressure processing chamber 110 (or 210) through a heat exchanger 630, through the pump 600, and back to the primary flow line 620. For example, a pump impeller 610 housed within pump 600 can move high pressure fluid from a suction side 622 of primary flow line 620 through an inlet 612 and through an outlet 614 to a pressure side 624 of the primary flow line 620. A fraction of high pressure fluid can be diverted through an inlet valve 628, through heat exchanger 630, and enter pump 600 through coolant inlet 632. Thereafter, the fraction of high pressure fluid utilized for cooling can exit from pump 600 at coolant outlet 634 and return to the primary flow line 620 through outlet valve 626.

Alternatively, as illustrated in FIG. 2B, another embodiment is provided for cooling pump 600 using a secondary flow line 640. A high pressure fluid, such as a supercritical fluid, from a fluid source (not shown) is directed through heat exchanger 630 (to lower the temperature of the fluid), and then enters pump 600 through coolant inlet 632, passes through pump 600, exits through coolant outlet 634, and continues to a discharge system (not shown). The fluid source can include a supercritical fluid source, such as a supercritical carbon dioxide source. The fluid source may or may not be a member of the high pressure fluid supply system 140 (or 240) described in FIG. 1 (or FIG. 4). The discharge system can include a vent, or the discharge system can include a recirculation system having a pump configured to recirculate the high pressure fluid through the heat exchanger 630 and pump 600.

Additional details regarding pump design are provided in co-pending U.S. patent application Ser. No. 10/987,066, Attorney Docket No. SSIT-120, entitled “Method and System for Cooling a Pump”; the entire content of which is herein incorporated by reference in its entirety.

Referring again to FIG. 1, the processing system 100 can comprise high pressure fluid supply system 140. The high pressure fluid supply system 140 can be coupled to the fluid flow system 120, but this is not required. In alternate embodiments, high pressure fluid supply system 140 can be configured differently and coupled differently. For example, the fluid supply system 140 can be coupled directly to the processing chamber 110. The high pressure fluid supply system 140 can include a supercritical fluid supply system. A supercritical fluid as referred to herein is a fluid that is in a supercritical state, which is that state that exists when the fluid is maintained at or above the critical pressure and at or above the critical temperature on its phase diagram. In such a supercritical state, the fluid possesses certain properties, one of which is the substantial absence of surface tension. Accordingly, a supercritical fluid supply system, as referred to herein, is one that delivers to a processing chamber a fluid that assumes a supercritical state at the pressure and temperature at which the processing chamber is being controlled. Furthermore, it is only necessary that at least at or near the critical point the fluid is in substantially a supercritical state at which its properties are sufficient, and exist long enough, to realize their advantages in the process being performed. Carbon dioxide, for example, is a supercritical fluid when maintained at or above a pressure of about 1070 psi at a temperature of 31° C. This state of the fluid in the processing chamber may be maintained by operating the processing chamber at 2000 to 10000 psi at a temperature, for example, of approximately 40° C. or greater.

As described above, the fluid supply system 140 can include a supercritical fluid supply system, which can be a carbon dioxide supply system. For example, the fluid supply system 140 can be configured to introduce a high pressure fluid having a pressure substantially near the critical pressure for the fluid. Additionally, the fluid supply system 140 can be configured to introduce a supercritical fluid, such as carbon dioxide in a supercritical state. Additionally, for example, the fluid supply system 140 can be configured to introduce a supercritical fluid, such as supercritical carbon dioxide, at a pressure ranging from approximately the critical pressure of carbon dioxide to 10,000 psi. Examples of other supercritical fluid species useful in the broad practice of the invention include, but are not limited to, carbon dioxide (as described above), oxygen, argon, krypton, xenon, ammonia, methane, methanol, dimethyl ketone, hydrogen, water, and sulfur hexafluoride. The fluid supply system can, for example, comprise a carbon dioxide source (not shown) and a plurality of flow control elements (not shown) for generating a supercritical fluid. For example, the carbon dioxide source can include a CO₂ feed system, and the flow control elements can include supply lines, valves, filters, pumps, and heaters. The fluid supply system 140 can comprise an inlet valve (not shown) that is configured to open and close to allow or prevent the stream of supercritical carbon dioxide from flowing into the processing chamber 110. For example, controller 150 can be used to determine fluid parameters such as pressure, temperature, process time, and flow rate.

Referring still to FIG. 1, the process chemistry supply system 130 is coupled to the recirculation system 120, but this is not required for the invention. In alternate embodiments, the process chemistry supply system 130 can be configured differently, and can be coupled to different elements in the processing system 100. The process chemistry is introduced by the process chemistry supply system 130 into the fluid introduced by the fluid supply system 140 at ratios that vary with the substrate properties, the chemistry being used and the process being performed in the processing chamber 110. Usually the ratio is roughly 1 to 15 percent by volume, which, for a chamber, recirculation system and associated plumbing having a volume of about one liter amounts to about 10 to 150 milliliters of process chemistry in most cases, but the ratio may be higher or lower.

The process chemistry supply system 130 can be configured to introduce one or more of the following process compositions, but not limited to: cleaning compositions for removing contaminants, residues, hardened residues, photoresist, hardened photoresist, post-etch residue, post-ash residue, post chemical-mechanical polishing (CMP) residue, post-polishing residue, or post-implant residue, or any combination thereof; cleaning compositions for removing particulate; drying compositions for drying thin films, porous thin films, porous low dielectric constant materials, or air-gap dielectrics, or any combination thereof; film-forming compositions for preparing dielectric thin films, metal thin films, or any combination thereof; healing compositions for restoring the dielectric constant of low dielectric constant (low-k) films; sealing compositions for sealing porous films; or any combination thereof. Additionally, the process chemistry supply system 130 can be configured to introduce solvents, co-solvents, surfactants, etchants, acids, bases, chelators, oxidizers, film-forming precursors, or reducing agents, or any combination thereof.

The process chemistry supply system 130 can be configured to introduce N-methyl pyrrolidone (NMP), diglycol amine, hydroxyl amine, di-isopropyl amine, tri-isopropyl amine, tertiary amines, catechol, ammonium fluoride, ammonium bifluoride, methylacetoacetamide, ozone, propylene glycol monoethyl ether acetate, acetylacetone, dibasic esters, ethyl lactate, CHF₃, BF₃, HF, other fluorine containing chemicals, or any mixture thereof. Other chemicals such as organic solvents may be utilized independently or in conjunction with the above chemicals to remove organic materials. The organic solvents may include, for example, an alcohol, ether, and/or glycol, such as acetone, diacetone alcohol, dimethyl sulfoxide (DMSO), ethylene glycol, methanol, ethanol, propanol, or isopropanol (IPA). For further details, see U.S. Pat. No. 6,306,564B1, filed May 27, 1998, and titled “REMOVAL OF RESIST OR RESIDUE FROM SEMICONDUCTORS USING SUPERCRITICAL CARBON DIOXIDE”, and U.S. Pat. No. 6,509,141B2, filed Sep. 3, 1999, and titled “REMOVAL OF PHOTORESIST AND PHOTORESIST RESIDUE FROM SEMICONDUCTORS USING SUPERCRITICAL CARBON DIOXIDE PROCESS,” both incorporated by reference herein.

Additionally, the process chemistry supply system 130 can comprise a cleaning chemistry assembly (not shown) for providing cleaning chemistry for generating supercritical cleaning solutions within the processing chamber. The cleaning chemistry can include peroxides and a fluoride source and/or an acid. For example, the peroxides can include hydrogen peroxide, benzoyl peroxide, or any other suitable peroxide, and the fluoride sources can include fluoride salts (such as ammonium fluoride salts), hydrogen fluoride, fluoride adducts (such as organo-ammonium fluoride adducts), and combinations thereof. The acid can, for example, contain hydrogen fluoride, trifluoroacidic acid, pyridine-hydrogen fluoride, ammonium fluoride, nitric acid, or phosphoric acid, or a combination of two or more thereof. Further details of fluoride sources and methods of generating supercritical processing solutions with fluoride sources are described in U.S. patent application Ser. No. 10/442,557, filed May 20, 2003, and titled “TETRA-ORGANIC AMMONIUM FLUORIDE AND HF IN SUPERCRITICAL FLUID FOR PHOTORESIST AND RESIDUE REMOVAL”, and U.S. patent application Ser. No. 10/321,341, filed Dec. 16, 2002, and titled “FLUORIDE IN SUPERCRITICAL FLUID FOR PHOTORESIST POLYMER AND RESIDUE REMOVAL,” both incorporated by reference herein.

Furthermore, the process chemistry supply system 130 can be configured to introduce chelating agents, complexing agents and other oxidants, organic and inorganic acids that can be introduced into the supercritical fluid solution with one or more carrier solvents, such as N,N-dimethylacetamide (DMAc), gamma-butyrolactone (BLO), dimethyl sulfoxide (DMSO), ethylene carbonate (EC), N-methyl pyrrolidone (NMP), dimethylpiperidone, propylene carbonate, and alcohols (such a methanol, ethanol and 2-propanol).

Moreover, the process chemistry supply system 130 can comprise a rinsing chemistry assembly (not shown) for providing rinsing chemistry for generating supercritical rinsing solutions within the processing chamber. The rinsing chemistry can include one or more organic solvents including, but not limited to, alcohols and ketones. In one embodiment, the rinsing chemistry can comprise sulfolane, also known as thiocyclopentane-1,1-dioxide, (cyclo)tetramethylene sulphone and 2,3,4,5-tetrahydrothiophene-1,1-dioxide, which can be purchased from a number of venders, such as Degussa Stanlow Limited, Lake Court, Hursley Winchester SO21 2LD UK.

Moreover, the process chemistry supply system 130 can be configured to introduce treating chemistry for curing, cleaning, healing (or restoring the dielectric constant of low-k materials), or sealing, or any combination, low dielectric constant films (porous or non-porous). The chemistry can include hexamethyldisilazane (HMDS), chlorotrimethylsilane (TMCS), trichloromethylsilane (TCMS), dimethylsilyldiethylamine (DMSDEA), tetramethyldisilazane (TMDS), trimethylsilyldimethylamine (TMSDMA), dimethylsilyldimethylamine (DMSDMA), trimethylsilyldiethylamine (TMSDEA), bistrimethylsilyl urea (BTSU), bis(dimethylamino)methyl silane (B[DMA]MS), bis (dimethylamino)dimethyl silane (B[DMA]DS), HMCTS, dimethylamino-pentamethyldisilane (DMAPMDS), dimethylaminodimethyldisilane (DMADMDS), disila-aza-cyclopentane (TDACP), disila-oza-cyclopentane (TDOCP), methyltrimethoxysilane (MTMOS), vinyltrimethoxysilane (VTMOS), or trimethylsilylimidazole (TMSI). Additionally, the chemistry may include N-tert-butyl-1,1-dimethyl-1-(2,3,4,5-tetramethyl-2,4-cyclopentadiene-1yl)silanamine, 1,3-dephenyl-1,1,3,3-tetramethyldisilazane, or tert-butylchlorodiphenylsilane. For further details, see U.S. patent application Ser. No. 10/682,196, filed Oct. 10, 2003, and titled “METHOD AND SYSTEM FOR TREATING A DIELECTRIC FILM,” and U.S. patent application Ser. No. 10/379,984, filed Mar. 4, 2003, and titled “METHOD OF PASSIVATING LOW DIELECTRIC MATERIALS IN WAFER PROCESSING,” both incorporated by reference herein.

In accordance with one embodiment of the present invention, the process chemistry supply system 130 is configured to introduce a process peroxide to the process chamber 110 with or in addition to the supercritical fluid. The process peroxide may be introduced during, for instance, cleaning processes. The process peroxide can be introduced as a component of one of the above types of process compositions or together with any one of the above process chemistries, or any mixture thereof. The process peroxide can include organic peroxides, or inorganic peroxides, or a combination thereof. For example, organic peroxides can include 2-butanone peroxide; 2,4-pentanedione peroxide; peracetic acid; t-butyl hydroperoxide; benzoyl peroxide; or m-chloroperbenzoic acid (mCPBA). Other process peroxides can include hydrogen peroxide. Alternatively, the process peroxide can include a diacyl peroxide, such as: decanoyl peroxide; lauroyl peroxide; succinic acid peroxide; or benzoyl peroxide; or any combination thereof. Alternatively, the process peroxide can include a dialkyl peroxide, such as: dicumyl peroxide; 2,5-di(t-butylperoxy)-2,5-dimethylhexane; t-butyl cumyl peroxide; α,α-bis(t-butylperoxy)diisopropylbenzene mixture of isomers; di(t-amyl) peroxide; di(t-butyl) peroxide; or 2,5-di(t-butylperoxy)-2,5-dimethyl-3-hexyne; or any combination thereof. Alternatively, the process peroxide can include a diperoxyketal, such as: 1,1-di(t-butylperoxy)-3,3,5-trimethylcyclohexane; 1,1-di(t-butylperoxy)cyclohexane; 1,1-di(t-amylperoxy)-cyclohexane; n-butyl 4,4-di(t-butylperoxy)valerate; ethyl 3,3-di-(t-amylperoxy)butanoate; t-butyl peroxy-2-ethylhexanoate; or ethyl 3,3-di(t-butylperoxy)butyrate; or any combination thereof. Alternatively, the process peroxide can include a hydroperoxide, such as: cumene hydroperoxide; or t-butyl hydroperoxide; or any combination thereof. Alternatively, the process peroxide can include a ketone peroxide, such as: methyl ethyl ketone peroxide; or 2,4-pentanedione peroxide; or any combination thereof. Alternatively, the process peroxide can include a peroxydicarbonate, such as: di(n-propyl)peroxydicarbonate; di(sec-butyl) peroxydicarbonate; or di(2-ethylhexyl)peroxydicarbonate; or any combination thereof. Alternatively, the process peroxide can include a peroxyester, such as: 3-hydroxyl-1,1-dimethylbutyl peroxyneodecanoate; α-cumyl peroxyneo-decanoate; t-amyl peroxyneodecanoate; t-butyl peroxyneodecanoate; t-butyl peroxypivalate; 2,5-di(2-ethylhexanoylperoxy)-2,5-dimethylhexane; t-amyl peroxy-2-ethylhexanoate; t-butyl peroxy-2-ethylhexanoate; t-amyl peroxy-acetate; t-butyl peroxyacetate; t-butyl peroxybenzoate; OO-(t-amyl) O-(2-ethylhexyl)monoperoxycarbonate; OO-(t-butyl) O-isopropyl monoperoxy-carbonate; OO-(t-butyl) O-(2-ethylhexyl) monoperoxycarbonate; polyether poly-t-butylperoxy carbonate; or t-butyl peroxy-3,5,5-trimethylhexanoate; or any combination thereof. Alternatively, the process peroxide can include any combination of peroxides listed above.

Initiator source 160 is configured to introduce an initiator, wherein the initiator is configured to catalyze the formation of a radical of the process peroxide. The initiator source 160 may include a chemical source as a part of the process chemistry supply system 130 configured to introduce a chemical initiator with the process peroxide. The chemical initiator can be a thermal initiator including: azo compounds, such as 2,2′-azobisisobutyronitrile (AIBN), 2,2′-azobis(2,4-dimethylpentanenitrile), or 1,1′-azobis(cyclohexanecarbo-nitrile); disulfides; or tetrazenes; or a combination thereof. When the thermal initiator is utilized with a process peroxide at elevated temperatures, the thermal dissociation of the initiator assists in the formation of the active radical species of the process peroxide. The optimal temperature for each initiator can vary from one initiator to the next. For example, when using an azo compound such as AIBN as an initiator, the temperature can range from approximately 50° C. to approximately 70° C.

Alternatively, the chemical initiator can be a redox initiator including: reducing agents, such as compounds containing Fe²⁺, Cr²⁺, V²⁺, Ti³⁺, Co²⁺, or Cu⁺; amines used in an organic media for acyl peroxides; a combination of inorganic reductants and inorganic oxidants, wherein reductants comprise HSO₃⁻, SO₃²⁻, S₂O₃²⁻, or S₂O₅²⁻, and oxidants comprise Ag⁺, Cu²⁺, Fe³⁺, ClO₃⁻, or H₂O₂; or an organic-inorganic redox pair, such as an alcohol with a compound containing Ce⁴⁺, V⁵⁺, Cr⁶⁺, or Mn³⁺, a thiol (such as thiouren, thioglycolic acid, etc.) with a compound containing CrO⁴⁻, SeO⁸⁻, Mn³⁺, or Fe³⁺, a carboxylic acid (such as oxalic acid, citric acid, etc.) with a compound containing Ce⁴⁺ or Mn³⁺, or an organometallic compound (e.g., Mo(CO)₆, Mn₂(CO)₁₀, ferrocene, or cobaltocene with an R-X compound, where R is an organic group and X is a halide).

Alternatively, the chemical initiator can include thiosulfate with acrylamide; methylacrylic acid; N,N-dimethylaniline with methylacrylate; a protonic acid; a lewis acid; a halide; or a nucleophile.

Alternatively, the chemical initiator can be a thermal initiator including: a second peroxide, different from the process peroxide introduced during, for instance, a cleaning process. The second peroxide is introduced as an initiator in an amount that is less than the amount of process peroxide introduced to perform the cleaning process. For example, the amount of the second peroxide may be equal to or less than approximately 10% by weight of the amount of the process peroxide. Additionally, the second peroxide, which acts as an initiator for the process peroxide, decomposes at a temperature that is less than the temperature at which the process peroxide decomposes. For example, when using a process peroxide for cleaning, wherein the process peroxide has a decomposition temperature greater than approximately 90° C., then some acetyl peroxides can be used as initiators within a temperature ranging from approximately 70° C. to approximately 90° C. In yet another example, when using a process peroxide for cleaning, wherein the process peroxide has a decomposition temperature greater than approximately 95° C., then benzoyl peroxide can be used as an initiator within a temperature ranging from approximately 80° C. to approximately 95° C. In yet another example, when using a process peroxide for cleaning, wherein the process peroxide has a decomposition temperature greater than approximately 140° C., then dicumyl or di-t-butyl peroxide can be used as an initiator within a temperature ranging from approximately 120° C. to approximately 140° C.

Alternatively, the initiator source 160 can comprise an electromagnetic (EM) source configured to introduce electro-magnetic (EM) radiation as an initiator. For example, the EM source can include a light source configured to introduce light, such as light at a specific wavelength to allow the process peroxide to absorb the light and dissociate into its active radical. The light source can, for instance, include a wavelength range from approximately 190 nm to approximately 800 nm.

The processing chamber 110 can be configured to process substrate 105 by exposing the substrate 105 to fluid from the fluid supply system 140, to process chemistry from the process chemistry supply system 130, and to an initiator from initiator source 160 (or EM source 170 below) in a processing space 112. Additionally, processing chamber 110 can include an upper chamber assembly 114, and a lower chamber assembly 115.

The upper chamber assembly 114 can comprise a heater (not shown) for heating the processing chamber 110, the substrate 105, or the processing fluid, or a combination of two or more thereof. Alternately, a heater is not required. Additionally, the upper chamber assembly 114 can include flow components for flowing a processing fluid through the processing chamber 110. In one example, a circular flow pattern can be established. Alternately, the flow components for flowing the fluid can be configured differently to affect a different flow pattern. Alternatively, the upper chamber assembly 114 can be configured to fill the processing chamber 110.

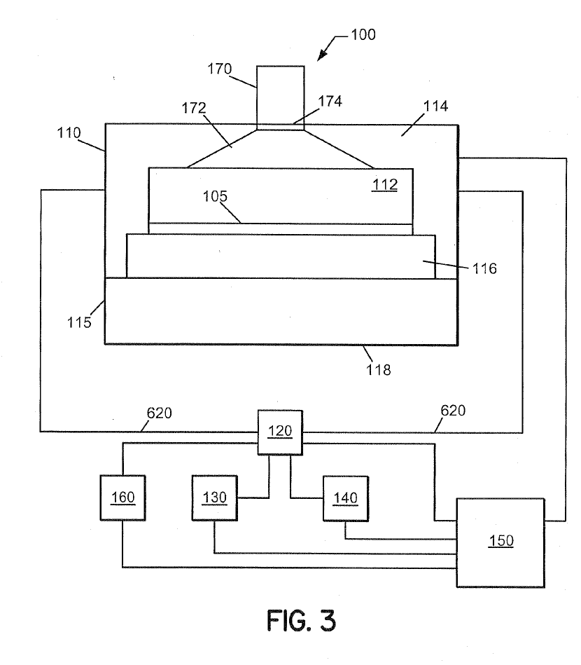

Referring now to FIG. 3, when electromagnetic (EM) radiation is utilized as an initiator for the process peroxide, the upper chamber assembly 114 can, for example, further include an EM source 170 configured to couple EM radiation with processing space 112 through view port 172 and optical window 174. The EM source 170 can, for example, comprise a light source configured to output light at a wavelength presented above.

Referring again to FIG. 1, the lower chamber assembly 115 can include a platen 116 configured to support substrate 105 and a drive mechanism 118 for translating the platen 116 in order to load and unload substrate 105, and seal lower chamber assembly 115 with upper chamber assembly 114. The platen 116 can also be configured to heat or cool the substrate 105 before, during, and/or after processing the substrate 105. For example, the platen 116 can include one or more heater rods configured to elevate the temperature of the platen to approximately 31° C. or greater. Additionally, the lower assembly 115 can include a lift pin assembly for displacing the substrate 105 from the upper surface of the platen 116 during substrate loading and unloading.

Additionally, controller 150 includes a temperature control system coupled to one or more of the processing chamber 110, the fluid flow system 120 (or recirculation system), the platen 116, the high pressure fluid supply system 140, or the process chemistry supply system 130. The temperature control system is coupled to heating elements embedded in one or more of these systems, and configured to elevate and maintain the temperature of the supercritical fluid to above the fluid's critical temperature, for example approximately 31° C. or greater. The heating elements can, for example, include resistive heating elements.

A transfer system (not shown) can be used to move a substrate into and out of the processing chamber 110 through a slot (not shown). In one example, the slot can be opened and closed by moving the platen 116, and in another example, the slot can be controlled using a gate valve (not shown).

The substrate can include semiconductor material, metallic material, dielectric material, ceramic material, or polymer material, or a combination of two or more thereof. The semiconductor material can include Si, Ge, Si/Ge, or GaAs. The metallic material can include Cu, Al, Ni, Pb, Ti, and/or Ta. The dielectric material can include silica, silicon dioxide, quartz, aluminum oxide, sapphire, low dielectric constant materials, Teflon®, and/or polyimide. The ceramic material can include aluminum oxide, silicon carbide, etc.

The processing system 100 can also comprise a pressure control system (not shown). The pressure control system can be coupled to the processing chamber 110, but this is not required. In alternate embodiments, the pressure control system can be configured differently and coupled differently. The pressure control system can include one or more pressure valves (not shown) for exhausting the processing chamber 110 and/or for regulating the pressure within the processing chamber 110. Alternately, the pressure control system can also include one or more pumps (not shown). For example, one pump may be used to increase the pressure within the processing chamber, and another pump may be used to evacuate the processing chamber 110. In another embodiment, the pressure control system can comprise seals for sealing the processing chamber. In addition, the pressure control system can comprise an elevator for raising and lowering the substrate 105 and/or the platen 116.

Furthermore, the processing system 100 can comprise an exhaust control system. The exhaust control system can be coupled to the processing chamber 110, but this is not required. In alternate embodiments, the exhaust control system can be configured differently and coupled differently. The exhaust control system can include an exhaust gas collection vessel (not shown) and can be used to remove contaminants from the processing fluid. Alternately, the exhaust control system can be used to recycle the processing fluid.

Referring now to FIG. 4, a processing system 200 is presented according to another embodiment. In the illustrated embodiment, processing system 200 comprises a processing chamber 210, a recirculation system 220, a process chemistry supply system 230, a fluid supply system 240, and a controller 250, all of which are configured to process substrate 205. The controller 250 can be coupled to the processing chamber 210, the recirculation system 220, the process chemistry supply system 230, and the fluid supply system 240. Alternately, controller 250 can be coupled to a one or more additional controllers/computers (not shown), and controller 250 can obtain setup and/or configuration information from an additional controller/computer.

As shown in FIG. 4, the recirculation system 220 can include a recirculation fluid heater 222, a pump 224, and a filter 226. The process chemistry supply system 230 can include one or more chemistry introduction systems, each introduction system having a chemical source 232, 234, 236, and an injection system 233, 235, 237. The injection systems 233, 235, 237 can include a pump (not shown) and an injection valve (not shown). One chemical source can, for example, include a peroxide source. Another chemical source can, for example, include an initiator source configured to introduce a chemical initiator.

Optionally, processing chamber 210 can comprise an EM source (not shown) as the initiator source to output EM radiation to serve as an initiator and facilitate the dissociation of the process peroxide.

Additional details regarding injection of process chemistry are provided in co-pending U.S. patent application Ser. No. 10/957,417, Attorney Docket No. SSIT-110, filed Oct. 1, 2004 and entitled “Method and System for Injecting Chemistry into a Supercritical Fluid”; the entire content of which is herein incorporated by reference in its entirety.

Furthermore, the fluid supply system 240 can include a supercritical fluid source 242, a pumping system 244, and a supercritical fluid heater 246. In addition, one or more injection valves, and/or exhaust valves may be utilized with the fluid supply system 240.

The processing chamber 210 can be configured to process substrate 205 by exposing the substrate 205 to fluid from the fluid supply system 240, to process chemistry from the process chemistry supply system 230, and to an initiator, either from process chemistry supply system 230 or from an EM source (not shown), in a processing space 212. Additionally, processing chamber 210 can include an upper chamber assembly 214, and a lower chamber assembly 215 having a platen 216 and drive mechanism 218, as described above with reference to FIG. 1.

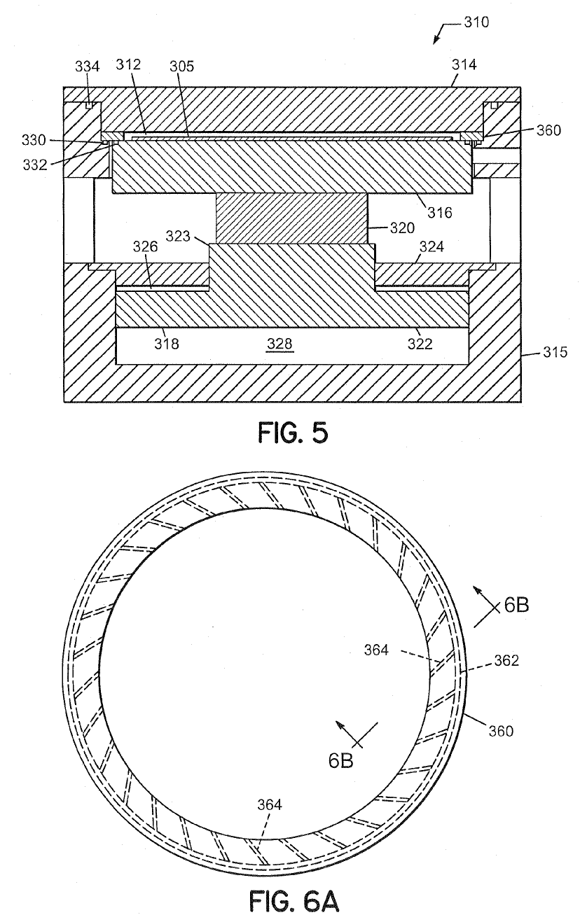

Alternatively, the processing chamber 210 can be configured as described in pending U.S. patent application Ser. No. 09/912,844 (U.S. Patent Application Publication No. 2002/0046707 A1), entitled “High pressure processing chamber for semiconductor substrates”, and filed on Jul. 24, 2001, which is incorporated herein by reference in its entirety. For example, FIG. 5 depicts a cross-sectional view of a supercritical processing chamber 310 comprising upper chamber assembly 314, lower chamber assembly 315, platen 316 configured to support substrate 305, and drive mechanism 318 configured to raise and lower platen 316 between a substrate loading/unloading condition and a substrate processing condition. Drive mechanism 318 can further include a drive cylinder 320, drive piston 322 having piston neck 323, sealing plate 324, pneumatic cavity 326, and hydraulic cavity 328. Additionally, supercritical processing chamber 310 further includes a plurality of sealing devices 330, 332, and 334 for providing a sealed, high pressure process space 312 in the processing chamber 310.

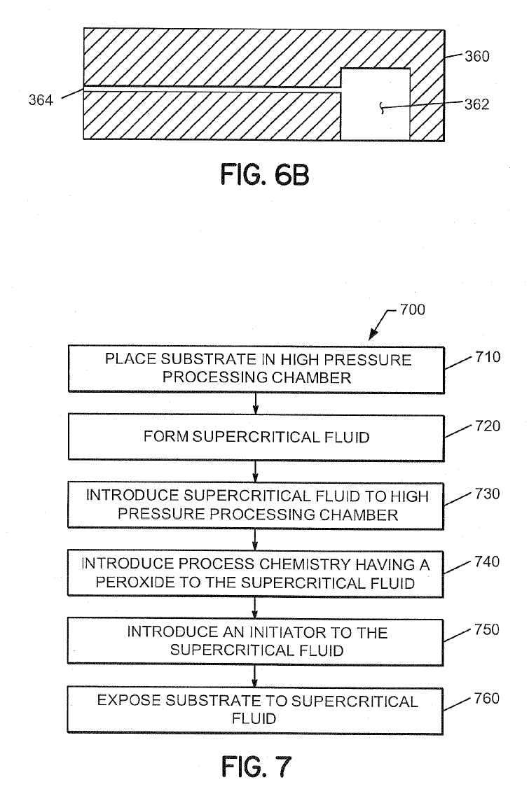

As described above with reference to FIGS. 1, 3, and 4, the fluid flow or recirculation system coupled to the processing chamber is configured to circulate the fluid through the processing chamber, and thereby permit the exposure of the substrate in the processing chamber to a flow of fluid. The fluid, such as supercritical carbon dioxide with process chemistry, can enter the processing chamber at a peripheral edge of the substrate through one or more inlets coupled to the fluid flow system. For example, referring now to FIG. 5 and FIGS. 6A and 6B, an injection manifold 360 is shown as a ring having an annular fluid supply channel 362 coupled to one or more inlets 364. The one or more inlets 364, as illustrated, include forty five (45) injection orifices canted at 45 degrees, thereby imparting azimuthal momentum, or axial momentum, or both, as well as radial momentum to the flow of high pressure fluid through process space 312 above substrate 305. Although shown to be canted at an angle of 45 degrees, the angle may be varied, including direct radial inward injection.

Additionally, the fluid, such as supercritical carbon dioxide, exits the processing chamber adjacent a surface of the substrate through one or more outlets (not shown). For example, as described in U.S. patent application Ser. No. 09/912,844, the one or more outlets can include two outlet holes positioned proximate to and above the center of substrate 305. The flow through the two outlets can be alternated from one outlet to the next outlet using a shutter valve.

Alternatively, the fluid, such as supercritical carbon dioxide, can enter and exit from the processing chamber 110 as described in pending U.S. patent application Ser. No. 10/______, Attorney Docket No. SSIT-115, filed on Dec. 20, 2004 and entitled “Method and System for Flowing a Supercritical Fluid in a High Pressure Processing System,” the entire content of which is herein incorporated by reference in its entirety.

Referring now to FIG. 7, a method of treating a substrate with a fluid in a supercritical state is provided. As depicted in flow chart 700, the method begins in 710 with placing a substrate onto a platen within a high pressure processing chamber configured to expose the substrate to a supercritical fluid processing solution.

In 720, a supercritical fluid is formed by bringing a fluid to a supercritical state by adjusting the pressure of the fluid to at or above the critical pressure of the fluid, and adjusting the temperature of the fluid to at or above the critical temperature of the fluid. In 730, the supercritical fluid is introduced to the high pressure processing chamber through one or more inlets and discharged through one or more outlets. The temperature of the supercritical fluid may be elevated to a value equal to or greater than 40° C. In one embodiment, the temperature of the supercritical fluid is elevated to greater than 80° C. to form a high temperature supercritical fluid. In a further embodiment, the temperature of the supercritical fluid is set to equal or greater than 120° C.

In 740, a process chemistry comprising a process peroxide is introduced to the supercritical fluid. The process peroxide can, for example, include any combination of peroxides presented above. Optionally, the process chemistry may include other process chemicals in addition to the process peroxide, as described above. In 750, an initiator is introduced to the supercritical fluid. The initiator can, for example, include any one or combination of chemical initiators presented above, or it may include EM radiation, or a combination thereof. In 760, the substrate is exposed to the supercritical fluid, process chemistry, and initiator.

Additional details regarding high temperature processing are provided in co-pending U.S. patent application Ser. No. 10/987,067, entitled “Method and System for Treating a Substrate Using a Supercritical Fluid”, Attorney Docket No. SSIT-117, filed on Nov. 12, 2004; the entire content of which is herein incorporated by reference in its entirety.

In yet another embodiment, the processes described herein can be further supplemented by ozone processing. For example, when performing a cleaning process, the substrate can be subjected to ozone treatment prior to treating with a supercritical processing solution. During ozone treatment, the substrate enters an ozone module, and the surface residues to be removed are exposed to an ozone atmosphere. For instance, a partial pressure of ozone formed in oxygen can be flowed over the surface of the substrate for a period of time sufficient to oxidize residues either partly or wholly. The ozone process gas flow rate can, for example, range from 1 to 50 slm (standard liters per minute) and, by way of further example, the flow rate can range from 5 to 15 slm. Additionally, the pressure can, for example, range from 1 to 5 atm and, by way of further example, range from 1 to 3 atm. Further details are provided in co-pending U.S. patent application Ser. No. 10/987,594, entitled “A Method for Removing a Residue From a Substrate Using Supercritical Carbon Dioxide Processing”, Attorney Docket No. SSIT-073, filed on Nov. 12, 2004, and co-pending U.S. patent application Ser. No. 10/987,676, entitled “A System for Removing a Residue From a Substrate Using Supercritical Carbon Dioxide Processing”, Attorney Docket No. SSIT-125, filed on Nov. 12, 2004; the entire contents of which are incorporated herein by reference in their entirety.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A method of treating a substrate comprising:
placing said substrate in a high pressure processing chamber onto a platen configured to support said substrate;
forming a supercritical fluid from a fluid by adjusting a pressure of said fluid above the critical pressure of said fluid, and adjusting a temperature of said fluid above the critical temperature of said fluid;
introducing said supercritical fluid to said high pressure processing chamber;
introducing a process chemistry comprising a process peroxide to said supercritical fluid;
introducing an initiator to said supercritical fluid, wherein said initiator facilitates the formation of a radical of said process peroxide; and
exposing said substrate to said supercritical fluid, said process chemistry and said initiator.

2. The method of claim 1, wherein said introducing said process chemistry comprising said process peroxide includes introducing a process chemistry comprising at least one of: 2-butanone peroxide; 2,4-pentanedione peroxide; peracetic acid; t-butyl hydroperoxide; benzoyl peroxide; m-chloroperbenzoic acid (mCPBA); hydrogen peroxide; decanoyl peroxide; lauroyl peroxide; succinic acid peroxide; dicumyl peroxide; 2,5-di(t-butylperoxy)-2,5-dimethylhexane; t-butyl cumyl peroxide; α,α-bis(t-butylperoxy)diisopropylbenzene mixture of isomers; di(t-amyl) peroxide; di(t-butyl) peroxide; 2,5-di(t-butylperoxy)-2,5-dimethyl-3-hexyne; 1,1-di(t-butylperoxy)-3,3,5-trimethylcyclohexane; 1,1-di(t-butylperoxy)cyclohexane; 1,1-di(t-amylperoxy)-cyclohexane; n-butyl 4,4-di(t-butylperoxy)valerate; ethyl 3,3-di-(t-amylperoxy)butanoate; t-butyl peroxy-2-ethylhexanoate; ethyl 3,3-di(t-butylperoxy)butyrate; cumene hydroperoxide; t-butyl hydroperoxide; methyl ethyl ketone peroxide; di(n-propyl)peroxydicarbonate; di(sec-butyl)peroxydicarbonate; di(2-ethylhexyl)peroxydicarbonate; 3-hydroxyl-1,1-dimethylbutyl peroxyneodecanoate; α-cumyl peroxyneodecanoate; t-amyl peroxyneodecanoate; t-butyl peroxyneodecanoate; t-butyl peroxypivalate; 2,5-di(2-ethylhexanoylperoxy)-2,5-dimethylhexane; t-amyl peroxy-2-ethylhexanoate; t-butyl peroxy-2-ethylhexanoate; t-amyl peroxyacetate; t-butyl peroxyacetate; t-butyl peroxybenzoate; OO-(t-amyl)O-(2-ethylhexyl)monoperoxycarbonate; OO-(t-butyl)O-isopropyl monoperoxycarbonate; OO-(t-butyl)O-(2-ethylhexyl)monoperoxycarbonate; polyether poly-t-butylperoxy carbonate; or t-butyl peroxy-3,5,5-trimethylhexanoate; or any combination thereof.

3. The method of claim 1, wherein said introducing said process chemistry comprising said process peroxide includes introducing a process chemistry comprising at least one of: a diacyl peroxide, a dialkyl peroxide, a diperoxyketal, a hydroperoxide, a ketone peroxide, a peroxydicarbonate, or a peroxyester, or any combination thereof.

4. The method of claim 1, wherein said introducing said process chemistry comprising said process peroxide comprises introducing an organic peroxide, or an inorganic peroxide, or any combination thereof.

5. The method of claim 1, wherein said introducing said initiator comprises introducing an azo compound, a disulfide, or a tetrazene, or a combination thereof.

6. The method of claim 1, wherein said introducing said initiator comprises introducing 2,2′-azobisisobutyronitrile (AIBN), 2,2′-azobis(2,4-dimethylpentanenitrile), or 1,1′-azobis(cyclohexanecarbonitrile), or a combination thereof.

7. The method of claim 6, further comprising:
elevating the temperature of said initiator to an optimal temperature ranging from approximately 50° C. to approximately 70° C.

8. The method of claim 1, wherein said introducing said initiator comprises introducing a compound comprising Fe²⁺, Cr²⁺, V²⁺, Ti³⁺, Co²⁺, or Cu⁺.

9. The method of claim 1, wherein said introducing said initiator comprises introducing a mixture of an inorganic reductant and an inorganic oxidant.

10. The method of claim 9, wherein said introducing said mixture of an inorganic reductant and an inorganic oxidant comprises introducing a reductant comprising HSO₃⁻, SO₃²⁻, S₂O₃²⁻ or S₂O₅²⁻, and introducing an oxidant comprising Ag⁻, Cu²⁺, Fe³⁺, ClO₃⁻, or H₂O₂.

11. The method of claim 1, wherein said introducing said initiator comprises introducing an organic-inorganic redox pair.

12. The method of claim 11, wherein said introducing said organic-inorganic redox pair comprises introducing an alcohol with a compound containing Ce⁴⁺, V⁵⁺, Cr⁶⁺, or Mn³⁺; a thiol with a compound containing CrO⁴⁻, SeO⁸⁻, Mn³⁺, or Fe³⁺; a carboxylic acid with a compound containing Ce⁴⁺ or Mn³⁺; or an organometallic compound.

13. The method of claim 12, wherein said introducing said thiol comprises introducing thiouren or thioglycolic acid.

14. The method of claim 12, wherein said introducing said carboxylic acid comprises introducing oxalic acid or citric acid.

15. The method of claim 12, wherein said introducing said organometallic compound comprises introducing Mo(CO)₆, Mn₂(CO)₁₀, ferrocene, or cobaltocene with an R—X compound, wherein R is an organic group and X is a halide.

16. The method of claim 1, wherein said introducing said initiator comprises introducing at least one of: thiosulfate with acrylamide; methylacrylic acid; N,N-dimethylaniline with methylacrylate; a protonic acid; a lewis acid, a halide, or a nucleophile.

17. The method of claim 1, further comprising:
recirculating said supercritical fluid past said substrate.

18. The method of claim 1, wherein said forming said supercritical fluid comprises forming supercritical carbon dioxide from carbon dioxide fluid.

19. The method of claim 18, wherein said adjusting said pressure above said critical pressure includes adjusting said pressure to a pressure in the range of approximately 1070 psi to approximately 10,000 psi.

20. The method of claim 18, wherein said adjusting said temperature above said critical temperature includes adjusting said temperature above approximately 31° C.

21. The method of claim 1, wherein said adjusting said temperature above said critical temperature includes adjusting said temperature above approximately 40° C.

22. The method of claim 1, wherein said adjusting said temperature above said critical temperature includes adjusting said temperature above approximately 80° C.

23. The method of claim 1, wherein said adjusting said temperature above said critical temperature includes adjusting said temperature to a temperature in the range of approximately 100° C. to approximately 300° C.

24. The method of claim 1, further comprising:
pre-heating said process chemistry prior to introducing said process chemistry to said supercritical fluid.

25. The method of claim 1, wherein said introducing said process chemistry comprising said process peroxide comprises introducing said process peroxide with one or more of a solvent, a co-solvent, a surfactant, or an etchant.

26. The method of claim 1, wherein said adjusting said pressure above said critical pressure includes adjusting said pressure to a pressure in the range of approximately 2000 psi to approximately 10,000 psi.

27. The method of claim 1, further comprising:
performing a series of decompression cycles, following said exposing said substrate; and
venting said high pressure processing system.

28. The method of claim 1, further comprising:
exposing said substrate to ozone.

29. The method of claim 28, wherein said exposing said substrate to said ozone precedes said exposing said substrate to said supercritical fluid, said process chemistry and said initiator.

30. The method of claim 1, wherein said introducing said initiator comprises introducing electromagnetic (EM) radiation.

31. The method of claim 30, wherein said introducing said EM radiation comprises introducing light having a wavelength in the range of approximately 190 nm to approximately 800 nm.

32. The method of claim 1, wherein said introducing said initiator comprises introducing a second peroxide different from said process peroxide, whereby said second peroxide decomposes at a second temperature less than a temperature at which said process peroxide decomposes.

33. The method of claim 32, wherein said introducing said second peroxide comprises introducing an amount of said second peroxide which is less than or equal to approximately 10% by weight of an amount of said process peroxide.

34. A high pressure processing system for treating a substrate comprising:
a processing chamber configured to treat said substrate;
a platen coupled to said processing chamber, and configured to support said substrate;
a high pressure fluid supply system configured to introduce a supercritical fluid to said processing chamber;
a fluid flow system coupled to said processing chamber, and configured to flow said supercritical fluid over said substrate in said processing chamber;
a process chemistry supply system having a peroxide source configured to introduce a process peroxide to said processing chamber;
an initiator source configured to introduce an initiator to said processing chamber to facilitate the formation of a radical of said process peroxide; and
a temperature control system coupled to one or more of said processing chamber, said platen, said high pressure fluid supply system, said fluid flow system, and said process chemistry supply system, and configured to elevate said supercritical fluid to a temperature approximately equal to 40° C., or greater.

35. The high pressure processing system of claim 34, wherein said fluid flow system comprises a recirculation system coupled to said processing chamber that forms a circulation loop with said processing chamber, wherein said recirculation system is configured to circulate said supercritical fluid through said processing chamber over said substrate.

36. The high pressure processing system of claim 34, wherein said platen provides a seal with said processing chamber in order to form a high pressure process space for treating said substrate.

37. The high pressure processing system of claim 34, wherein said high pressure fluid supply system includes a carbon dioxide source to introduce supercritical carbon dioxide (CO₂) fluid.

38. The high pressure processing system of claim 34, wherein said processing chamber is further coupled to an ozone processing chamber configured to expose said substrate to ozone.

39. The high pressure processing system of claim 34, wherein said initiator source comprises a chemical source configured to introduce a chemical initiator.

40. The high pressure processing system of claim 34, wherein said initiator source comprises an electromagnetic (EM) radiation source configured to introduce EM radiation.
